(19) United States
(12) Patent Application Publication
(10) Pub. No.: US 2025/0219646 A1
(43) Pub. Date: Jul. 3, 2025

(54) ANALOG-TO-DIGITAL CONVERTER CIRCUIT AND METHOD AND DEVICE USING THE SAME

(71) Applicant: Samsung Electronics Co., Ltd., Suwon-si (KR)

(72) Inventors: Joonseong KANG, Suwon-si (KR); Chisung BAE, Suwon-si (KR); Jin-O SEO, Suwon-si (KR); Hyeokki HONG, Suwon-si (KR)

(73) Assignee: Samsung Electronics Co., Ltd., Suwon-si (KR)

(21) Appl. No.: 18/944,726

(22) Filed: Nov. 12, 2024

(30) Foreign Application Priority Data
Dec. 27, 2023 (KR) 10-2023-0193211

(51) Int. Cl. H03M 1/06; H03M 1/08

(52) U.S. Cl. CPC H03M 1/0687; H03M 1/0626; H03M 1/0836

(57) ABSTRACT

An analog-to-digital converter (ADC) circuit includes an ADC module configured to convert an analog input signal into an original digital output signal, an error detection module configured to detect overflow of the original digital output signal due to the analog input signal being out of an input dynamic range of the ADC module and determine a current state of the original digital output signal as a normal state or an error state, and a correction module configured to, in response to the current state of the original digital output signal being the normal state, output a corrected digital output signal based on the original digital output signal and, in response to the current state of the original digital output signal being the error state, output the corrected digital output signal based on a replacement output signal for replacing the original digital output signal.

### CROSS-REFERENCE TO RELATED APPLICATIONS

This application claims the benefit under 35 USC § 119 (a) of Korean Patent Application No. 10-2023-0193211, filed on Dec. 27, 2023 in the Korean Intellectual Property Office, the entire disclosure of which is incorporated herein by reference for all purposes.

### BACKGROUND

### 1. Field

The following description relates to an analog-to-digital converter (ADC) circuit and a method and device using the same.

### 2. Description of Related Art

Biosignal technology may include biosignal measurement, analysis of measurement results, and stimulation. A living body may be a part or the whole body of various living organisms, such as the human body, animals, and plants, and biosignal technology may include identifying biological structures, biological functions, etc. Since a biosignal is an analog signal, for analysis, a biosignal may be converted into a digital signal. An analog signal may be converted into a digital signal using an analog-to-digital converter (ADC). An ADC may convert analog signals collected from the natural world into a digital format that a computer can understand.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, an analog-to-digital converter (ADC) circuit includes an ADC module configured to convert an analog input signal into an original digital output signal, an error detection module configured to detect overflow of the original digital output signal due to the analog input signal being out of an input dynamic range of the ADC module and determine a current state of the original digital output signal as a normal state or an error state, and a correction module configured to, in response to the current state of the original digital output signal being the normal state, output a corrected digital output signal based on the original digital output signal, and, in response to the current state of the original digital output signal being the error state, output the corrected digital output signal based on a replacement output signal for replacing the original digital output signal.

The ADC module may include a digital-to-analog converter (DAC) module configured to convert a previous original digital output signal into a previous analog output signal, an adjustment module configured to adjust the analog input signal using the previous analog output signal, an oscillator module configured to generate an oscillator signal controlled by an output signal of the adjustment module, and a phase detection and quantization module configured to perform phase detection and quantization on the oscillator signal to generate the original digital output signal.

For the detecting of the overflow, the error detection module may be configured to detect the overflow of the original digital output signal based on a difference between the original digital output signal and a previous original digital output signal.

For the determining of the current state, the error detection module may be configured to, in response to the current state of the original digital output signal being the normal state and the difference between the original digital output signal and the previous original digital output signal exceeding a first threshold value, determine the current state of the original digital output signal as the error state.

For the determining of the current state, the error detection module may be configured to, in response to the current state of the original digital output signal being the error state and the difference between the original digital output signal and the previous original digital output signal being less than a second threshold value, determine the current state of the original digital output signal as the normal state.

For the determining of the current state, the error detection module may be configured to, in response to a state in which the difference between the original digital output signal and the previous original digital output signal is less than a second threshold value persisting for a threshold time, determine the current state of the original digital output signal as the normal state.

The correction module may include a buffer module configured to store original digital values of the original digital output signal, a delay selection module configured to select one of the original digital values as a temporary value from the buffer module based on a delay value that is set to correspond to a delay of the corrected digital output signal, and an output selection module configured to select the temporary value or a replacement value as a digital value of the corrected digital output signal based on the current state of the original digital output signal.

The correction module further may include a comparison module configured to compare the temporary value to a reference value.

The replacement value may include a first sub-replacement value and a second sub-replacement value, and, for the selecting of the temporary value or the replacement value, the output selection module may be configured to, in response to the replacement value being selected as the digital value of the corrected digital output signal, select the first sub-replacement value or the second sub-replacement value as the digital value of the corrected digital output signal based on a comparison result between the temporary value and the reference value.

The replacement value may be a boundary value of the original digital output signal or a temporary restoration value of a replacement waveform for temporarily restoring a waveform of the analog input signal that is out of the input dynamic range.

The ADC circuit may include a memory configured to store temporary restoration values of the replacement waveform including the temporary restoration value.

The ADC circuit may include a digital filter configured to perform digital filtering of the corrected digital output signal and a decimation filter configured to perform decimation on an output of the digital filter.

The ADC circuit may be a delta sigma (DS) ADC.

The ADC circuit may be a voltage-controlled oscillator (VCO)-based DS ADC.

In one or more general aspects, an electronic device includes the ADC circuit and one or more processors configured to determine biometric information of one or more nerves based on the corrected digital output signal, wherein the analog input signal is measured from the one or more nerves.

In one or more general aspects, an electronic device includes signal measuring instruments configured to determine digital output signals corresponding to analog input signals measured from nerves, the signal measuring instruments comprising an analog-to-digital converter (ADC) circuit comprising an analog-to-digital converter (ADC) module configured to convert an analog input signal of the analog input signals into an original digital output signal, an error detection module configured to detect overflow of the original digital output signal due to the analog input signal being out of an input dynamic range of the ADC module and determine a current state of the original digital output signal as a normal state or an error state, and a correction module configured to, in response to the current state of the original digital output signal being the normal state, output a digital output signal of the digital output signals based on the original digital output signal, and, in response to the current state of the original digital output signal being the error state, output the digital output signal of the digital output signals based on a replacement output signal for replacing the original digital output signal, and one or more processors configured to determine biometric information of the nerves based on the digital output signals including the output digital output signal.

The biometric information may include any one or any combination of any two or more of a neural signal, a neural response, connectivity of nerves, and connection strength of nerves.

For the detecting of the overflow, the error detection module may be configured to detect the overflow of the original digital output signal based on a difference between the original digital output signal and a previous original digital output signal.

For the determining of the current state, the error detection module may be configured to, in response to the current state of the original digital output signal being the normal state and the difference between the original digital output signal and the previous original digital output signal exceeding a first threshold value, determine the current state of the original digital output signal as the error state.

In one or more general aspects, a signal processing method includes converting an analog input signal into an original digital output signal, detecting overflow of the original digital output signal due to the analog input signal being out of an input dynamic range of an analog-to-digital converter (ADC) module and determining a current state of the original digital output signal as a normal state or an error state, outputting a corrected digital output signal based on the original digital output signal, in response to the current state of the original digital output signal being the normal state, and outputting the corrected digital output signal based on a replacement output signal for replacing the original digital output signal, in response to the current state of the original digital output signal being the error state.

Other features and aspects will be apparent from the following detailed description, the drawings, and the claims.

### BRIEF DESCRIPTION OF THE DRAWINGS

FIG. 1 illustrates an example of a configuration of an analog-to-digital converter (ADC) circuit.

FIG. 2A illustrates an example of an input dynamic range of an ADC circuit, and FIG. 2B illustrates an example of a relationship between an actual amplitude and an inaccurate amplitude of an input that is out of an input dynamic range of an ADC circuit.

FIG. 3A illustrates an example of an internal configuration of an error detection and correction block and FIG. 3B illustrates an example of a configuration of an error detection block and a correction block.

FIG. 4 illustrates an example of states of an original digital output signal.

FIG. 5 illustrates an example of a configuration of an ADC circuit including a memory.

FIG. 6 illustrates an example of an effect of overflow of an original digital output signal.

FIG. 7 illustrates an example of a corrected digital output signal based on a replacement output signal.

FIG. 8 illustrates an example of a signal processing method using an ADC circuit.

FIG. 9 illustrates an example of a process in which a corrected digital output signal is generated based on a current state of an original digital output signal.

FIG. 10 illustrates an example of a configuration of an electronic device using an ADC circuit.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which the present disclosure pertains and based on an understanding of the disclosure of the present application. Terms, such as those defined in commonly used dictionaries, should be construed to have meanings matching with contextual meanings in the relevant art and the disclosure of the present application, and are not to be construed to have an ideal or excessively formal meaning unless otherwise defined herein.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Hereinafter, examples will be described in detail with reference to the accompanying drawings. When describing the examples with reference to the accompanying drawings, like reference numerals refer to like components and a repeated description related thereto will be omitted.

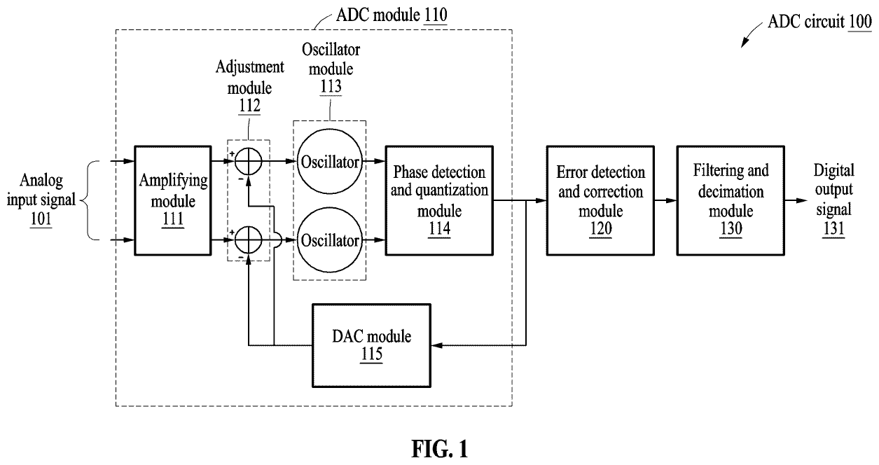

FIG. 1 illustrates an example of a configuration of an analog-to-digital converter (ADC) circuit. Referring to FIG. 1, an ADC circuit 100 may generate a digital output signal 131 corresponding to an analog input signal 101. The ADC circuit 100 may include an ADC module 110 (e.g., one or more ADCs), an error detection and correction module 120 (e.g., one or more error detectors and correctors), and a filtering and decimation module 130 (e.g., a filter and decimator).

The ADC module 110 may convert the analog input signal 101 into an original digital output signal. The ADC module 110 may include an amplifying module 111 (e.g., one or more amplifiers), an adjustment module 112 (e.g., one or more adjusters), an oscillator module 113 (e.g., one or more oscillators), a phase detection and quantization module 114 (e.g., one or more phase detectors and quantizers), and a digital-to-analog converter (DAC) module 115 (e.g., one or more DACs).

The ADC module 110 may be based on a delta sigma (DS) ADC. For example, the ADC module 110 may be a DS ADC. The DS ADC is a type of ADC and may operate by correcting an output signal (e.g., a digital signal corresponding to a conversion result) based on the difference between an input signal and the output signal. Since the DS ADC has relatively many parts that may be implemented digitally, an implementation area may be effectively reduced when using a fine complementary metal-oxide-semiconductor (CMOS) process. In addition, due to unique operation characteristics of the DS ADC, a frequency component of a quantization error that occurs when converting to digital data may be adjusted. The frequency component may be adjusted by noise shaping. Subsequently, the frequency component may be removed through a digital filter and low-noise digital data may be obtained. The DS ADC may be used effectively when a chip size is limited or a multi-channel low-noise ADC is required. The DS ADC may also be used in a multi-channel neural network neural signal measurement system.

The ADC module 110 may be based on a voltage-controlled oscillator (VCO)-based DS ADC. For example, the ADC module 110 may be a VCO-based DS ADC. The VCO-based DS ADC may be an ADC that implements an operation of the DS ADC based on a VCO. The VCO may generate signals at different frequencies depending on the amplitude of a control signal. In the VCO-based DS ADC, the difference between the input signal and the output signal may be used as the control signal of the VCO. A function of the DS ADC may be implemented by processing the frequency of an oscillation signal that is output according to the control signal. The VCO-based DS ADC may maximize advantages of digital implementation. The VCO may be implemented as a ring oscillator, and a method of detecting a phase-based frequency of an oscillation signal of the VCO may be used in the VCO-based DS ADC, since both the ring oscillator and the method of detecting a phase-based frequency are suitable for digital implementation.

The amplifying module 111 may amplify the analog input signal 101. For example, the amplifying module 111 may be or include an operational transconductance amplifier (OTA). However, examples are not limited thereto. When the amplifying module 111 includes the OTA, the analog input signal 101 may be a voltage signal and an output signal of the amplifying module 111 may be a current signal. Referring to FIG. 1, the analog input signal 101 is shown as a differential signal and the ADC module 110 is shown as having a configuration for a differential signal, but examples are not limited thereto. The analog input signal 101 may be a single-ended signal. For example, the ADC module 110 may have a configuration for the single-ended signal.

The DAC module 115 may convert a previous original digital output signal into a previous analog output signal. The previous original digital output signal may refer to an original digital output signal generated at a previous time. The adjustment module 112 may adjust the analog input signal 101 using the previous analog output signal. The adjustment module 112 may be or include one or more adders. The analog input signal 101 may be an output of the amplifying module 111. The adjustment module 112 may adjust the analog input signal 101 through a control technique of the DS ADC.

The oscillator module 113 may generate an oscillator signal that is controlled by an output signal of the adjustment module 112. The oscillator module 113 may be or include one or more oscillators. A frequency of the oscillator signal may be adjusted by the output signal of the adjustment module 112. The phase detection and quantization module 114 may perform phase detection and quantization on the oscillator signal to generate an original digital output signal. When the analog input signal 101 corresponds to a differential signal, the oscillator signal may also correspond to a differential signal and the frequency difference of the differential oscillator signal may be converted into a phase difference through signal integration. The original digital output signal may be generated according to quantization based on the phase difference.

When the ADC module 110 uses a phase, the ADC module 110 may have an input dynamic range. The input dynamic range may represent a range of the amplitude of an input signal, in which the input signal may be converted into a digital signal without ambiguity. When the analog input signal 101 is out of the input dynamic range of the ADC module 110, overflow may occur in the original digital output signal. Overflow may refer to a state of an original digital signal in which an expression value of the original digital signal does not reflect an actual value.

The error detection and correction module 120 may detect the overflow, may determine a current state of the original digital output signal as a normal state or an error state, and may output a corrected digital output signal based on the determined current state of the original digital output signal. When the current state of the original digital output signal is the normal state, the error detection and correction module 120 may output the corrected digital output signal based on the original digital output signal and when the current state of the original digital output signal is the error state, the error detection and correction module 120 may output the corrected digital output signal based on a replacement output signal for replacing the original digital output signal.

The filtering and decimation module 130 may be or include a digital filter for performing digital filtering of the corrected digital output signal and a decimation filter for performing decimation on an output of the digital filter. The digital output signal 131 may be a result of filtering and decimation on the corrected digital output signal.

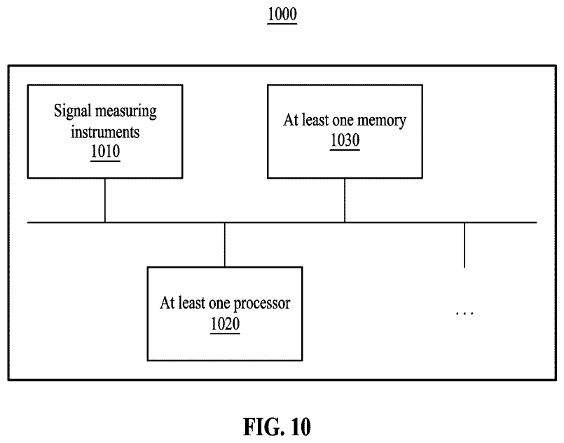

The analog input signal 101 may be measured from nerves. Biometric information of nerves may be determined (e.g., by at least one processor 1020 of FIG. 10) based on the digital output signal 131. The biometric information may include a nerve signal, a nerve response, connectivity of nerves, connection strength of nerves, and/or a combination thereof.

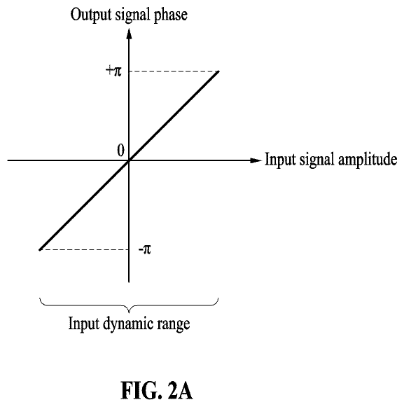

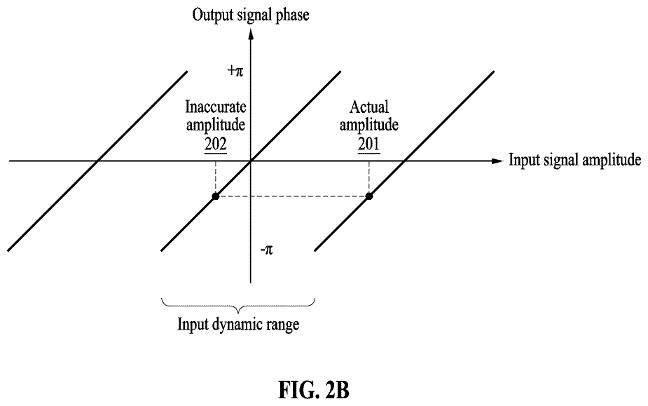

FIG. 2A illustrates an example of an input dynamic range of an ADC circuit, and FIG. 2B illustrates an example of a relationship between an actual amplitude and an inaccurate amplitude of an input that is out of an input dynamic range of an ADC circuit. Referring to FIG. 2A, the amplitude of an input signal within an input dynamic range may be normally mapped to a phase of an output signal. The phase of the output signal may be normally expressed within a 2 pi (π) range corresponding to the input dynamic range. Referring to FIG. 2B, when the amplitude of the input signal is out of the input dynamic range, an actual amplitude 201 may be incorrectly measured as an inaccurate amplitude 202. According to examples, a method and device of one or more embodiments may detect overflow due to an analog input signal being out of an input dynamic range of an ADC module and output a corrected digital output signal of an original digital output signal.

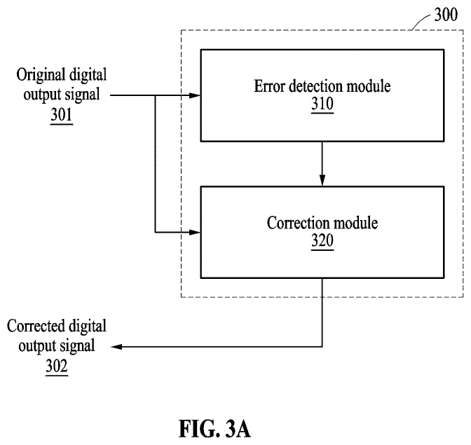

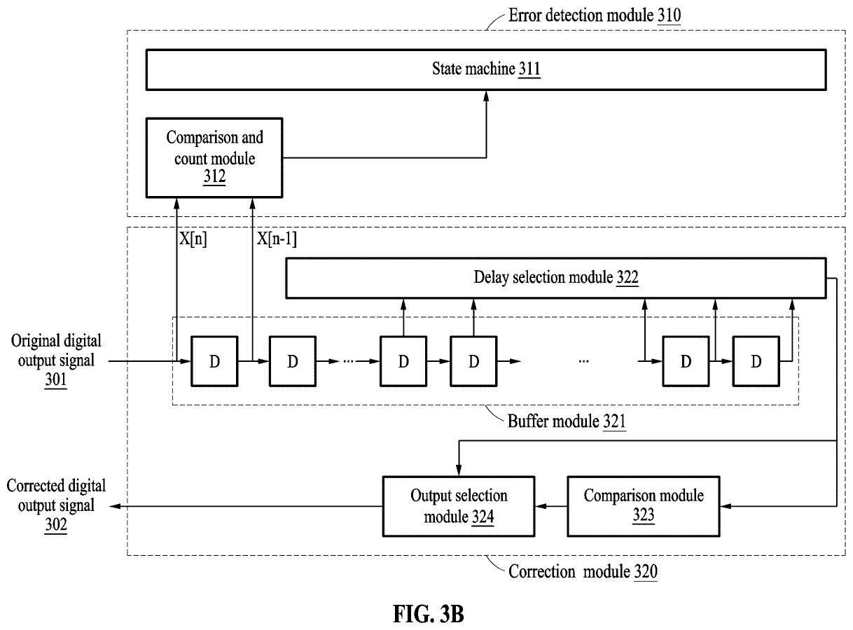

FIG. 3A illustrates an example of an internal configuration of an error detection and correction module. Referring to FIG. 3A, an error detection and correction module 300 may include an error detection module 310 (e.g., an error detector) for detecting overflow of an original digital output signal 301 due to an analog input signal being out of an input dynamic range of an ADC module and determining a current state of the original digital output signal 301 as a normal state or an error state, and a correction module 320 (e.g., a corrector) for outputting a corrected digital output signal 302 based on the original digital output signal 301, when the current state of the original digital output signal 301 is the normal state, and outputting the corrected digital output signal 302 based on a replacement output signal for replacing the original digital output signal 301, when the current state of the original digital output signal 301 is the error state. For example, the replacement output signal may be a signal with a constant value or a signal with a particular replacement waveform.

The error detection module 310 may detect the overflow of the original digital output signal 301 based on the difference between the original digital output signal 301 and a previous original digital output signal. For example, the original digital output signal 301 may be a current value of the original digital output signal 301 and the previous original digital output signal may be a previous value of the original digital output signal 301.

When the current state of the original digital output signal 301 is the normal state and the difference between the original digital output signal 301 and the previous original digital output signal exceeds a first threshold value, the error detection module 310 may determine the current state of the original digital output signal 301 as the error state. When the current state of the original digital output signal 301 is the error state and the difference between the original digital output signal 301 and the previous original digital output signal is less than a second threshold value, the error detection module 310 may determine the current state of the original digital output signal 301 as the normal state. When a state in which the difference between the original digital output signal 301 and the previous original digital output signal is less than a second threshold value persists for a threshold time, the error detection module 310 may determine the current state of the original digital output signal 301 as the normal state.

FIG. 3B illustrates an example of a configuration of an error detection module and a correction module. Referring to FIG. 3B, an error detection module 310 may include a state machine 311 and a comparison and count module 312 (e.g., one or more comparators and counters). A correction module 320 may include a buffer module 321 (e.g., one or more buffers), a delay selection module 322 (e.g., a delay selector), a comparison module 323 (e.g., one or more comparators), and an output selection module 324 (e.g., an output selector).

The state machine 311 may represent the current state of the original digital output signal 301 as the normal state or the error state. The comparison and count module 312 may determine the difference between a current digital value X[n] and a previous digital value X[n−1] of the original digital output signal 301. When the current state is the normal state and the difference therebetween exceeds the first threshold value, the comparison and count module 312 may convert the current state from the normal state to the error state. When the current state is the error state and the difference is less than the second threshold value, the comparison and count module 312 may convert the current state from the error state to the normal state. When the difference therebetween is less than the second threshold value, the comparison and count module 312 may not immediately convert the current state from the error state to the normal state. For example, when a state in which the difference therebetween is less than the second threshold value persists for a threshold time, the comparison and count module 312 may convert the current state from the error state to the normal state. For example, when the difference therebetween has been less than the second threshold value for a predetermined number of time iterations, the comparison and count module 312 may convert the current state from the error state to the normal state. For example, when the difference between the digital value X[n] and the digital value X[n−1], the difference between the digital value X[n−1] and a digital value X[n−2], . . . , and the difference between a digital value X[n−(N−1)] and a digital value X[n−N] (where N is a predetermined natural number greater than n) are each less than the second threshold value, the comparison and count module 312 may convert the current state from the error state to the normal state. The second threshold value may be less than the first threshold value. The conditions for converting the error state to the normal state may be defined more strictly than the conditions for converting the normal state to the error state, as the conditions for converting the error state to the normal state require the threshold time and the second threshold value to be less than the first threshold value.

The correction module 320 may generate the corrected digital output signal 302 based on the original digital output signal 301. The original digital output signal 301 may be represented by X and the corrected digital output signal 302 may be represented by Y. The buffer module 321 may store original digital values (e.g., X[n] and X[n−1]) of the original digital output signal 301. The delay selection module 322 may select one of the original digital values as a temporary value from the buffer module 321 based on a delay value set to correspond to a delay of the corrected digital output signal 302. The output selection module 324 may select the temporary value or a replacement value as a digital value of the corrected digital output signal 302 based on the current state of the original digital output signal 301.

The comparison module 323 may compare the temporary value to a reference value. The replacement value may include a first sub-replacement value and a second sub-replacement value. When the output selection module 324 selects the replacement value as the digital value of the corrected digital output signal 302, the output selection module 324 may select the first sub-replacement value or the second sub-replacement value as the digital value of the corrected digital output signal 302 based on a comparison result between the temporary value and the reference value. For example, the reference value may be 0, a first replacement value may be a positive replacement value, and a second replacement value may be a negative replacement value. When the temporary value is greater than 0, the output selection module 324 may select the positive replacement value as the digital value of the corrected digital output signal 302 and when the temporary value is less than 0, the output selection module 324 may select the negative replacement value as the digital value of the corrected digital output signal 302.

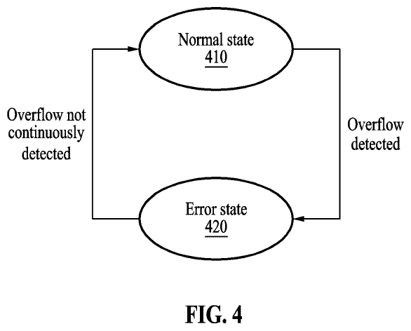

FIG. 4 illustrates an example of states of an original digital output signal. Referring to FIG. 4, a current state of the original digital output signal may include a normal state 410 and an error state 420. The normal state 410 and the error state 420 may be defined by a state diagram of a state machine. In the normal state 410, a corrected digital output signal may be output based on the original digital output signal. The corrected digital output signal in the normal state 410 may be expressed as Y [n]=X[n-DELAY]. X may represent the original digital output signal, Y may represent the corrected digital output signal, n may represent a sampling index, and DELAY may represent a delay value. The difference between the original digital output signal and the corrected digital output signal may correspond to a delay. A temporary value may be expressed as TMP_X=X[n-DELAY]. TMP_X may represent the temporary value. The temporary value may be determined at the normal state 410.

When overflow is detected, the current state may be converted from the normal state 410 to the error state 420. A condition for the conversion may be expressed as ABS (X[n]−X[n−1])>THRES1. ABS may represent an absolute value and THRES1 may represent a first threshold.

In the error state 420, the corrected digital output signal may be output based on a replacement output signal for replacing the original digital output signal. The corrected digital output signal of the error state 420 may be expressed as Y [n]=A1 (TMP_X>REFR), Y [n]=A2 (TMP_X<REFR). A1 may represent a first sub-replacement value, A2 may represent a second sub-replacement value, and RFER may represent a reference value. For example, a replacement value may be a boundary value of the original digital output signal. For example, when the original digital output signal has a minimum value of −16 and a maximum value of 15, the first sub-replacement value of the replacement value may be 15 and the second sub-replacement value of the replacement value may be −16. The reference value may be 0. In another example, the replacement value may be a temporary restoration value of a replacement waveform for temporarily restoring a waveform of an analog input signal that is out of an input dynamic range.

When overflow is not continuously detected, the current state may be converted from the error state 420 to the normal state 410. A condition for the conversion may be expressed as ABS (X[n]−X[n−1])<THRES2 occurring CNT times continuously. THRES2 may represent a second threshold and CNT may represent a threshold count value corresponding to a threshold time.

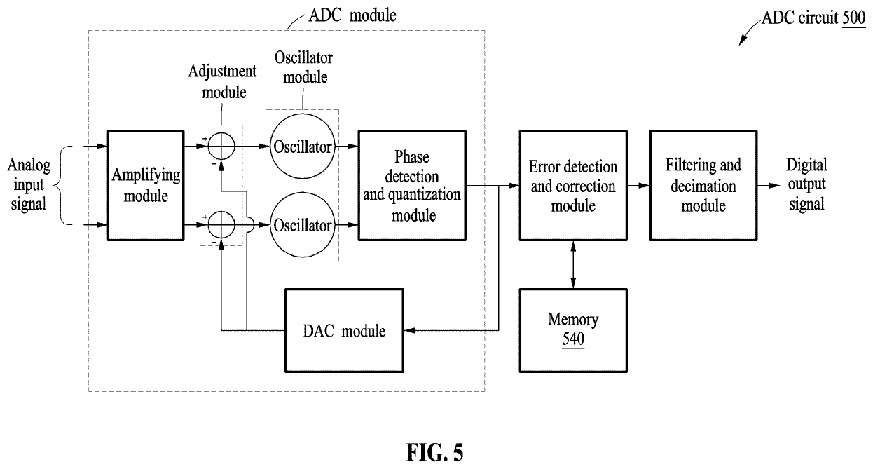

FIG. 5 illustrates an example of a configuration of an ADC circuit including a memory. Referring to FIG. 5, an ADC circuit 500 of FIG. 5 may further include a memory 540 (e.g., one or more memories). The memory 540 may store temporary restoration values of a replacement waveform including a temporary restoration value. When a boundary value is used as a replacement value, a corrected digital output signal may have a predetermined value in an error state and when the temporary restoration value of the replacement waveform is used as a replacement value, the corrected digital output signal may have a waveform corresponding to the replacement waveform in the error state.

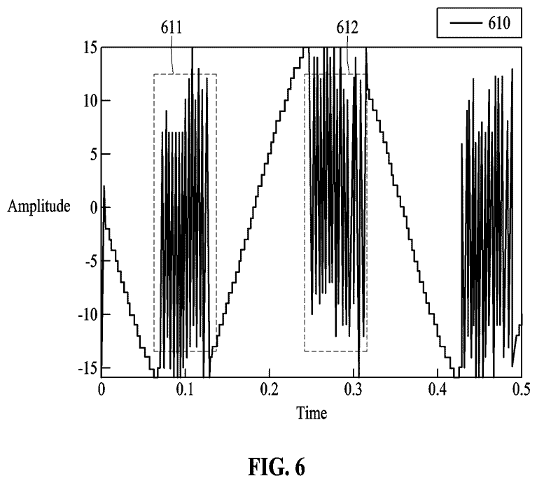

FIG. 6 illustrates an example of an effect of overflow of an original digital output signal. Referring to FIG. 6, when overflow occurs in an original digital output signal 610, the original digital output signal 610 may include error output values 611 and 612 instead of normal output values corresponding to an analog input signal.

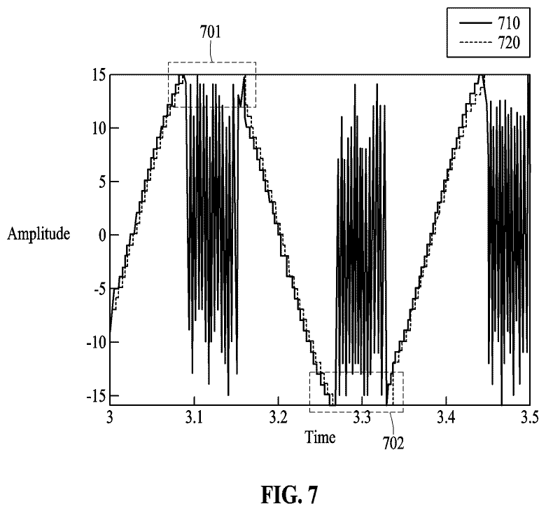

FIG. 7 illustrates an example of a corrected digital output signal based on a replacement output signal. Referring to FIG. 7, a corrected digital output signal 720 may include replacement values 701 and 702 of a replacement output signal instead of error output values of an original digital output signal 710. When a temporary value of the original digital output signal 710 is greater than a reference value, the replacement values 701 may correspond to selected first sub-replacement values and when a temporary value of the original digital output signal 710 is less than the reference value, the replacement values 702 may correspond to selected second sub-replacement values. The replacement values 701 and 702 may correspond to a boundary value of the original digital output signal 710. A temporary restoration value of a replacement waveform may be used to temporarily restore a waveform of an analog input signal that is out of an input dynamic range instead of the boundary value of the original digital output signal 710.

In general, a waveform of a nerve signal is known to be in the form of a spike with a short amplitude. When analyzing the waveform of the measured nerve signal, the size of the signal does not change significantly for most of the time and the signal keeps being high or low only for a short period of time. When a neural signal is measured for the purpose of analyzing a neural network configuration, it may be important to measure a signal level (e.g., post-synaptic potential (PSP)) of the occurrence time of a spike waveform of the neural signal and before the occurrence of the spike waveform of the neural signal, rather than measure the entire spike waveform of the neural signal. An ADC circuit of one or more embodiments may manage with overflow when analyzing the neural network configuration by using a corrected digital output signal based on the replacement output signal without adjusting an input gain or an additional analog circuit.

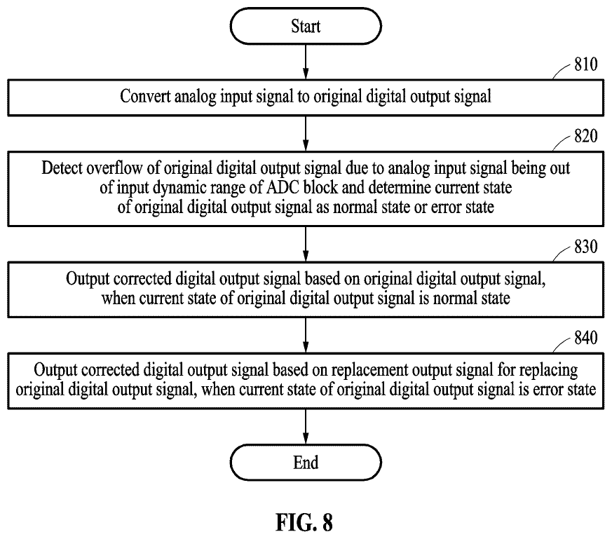

FIG. 8 illustrates an example of a signal processing method using an ADC circuit. Operations 810 to 840 to be described hereinafter may be performed sequentially in the order and manner as shown and described below with reference to FIG. 8, but the order of one or more of the operations may be changed, one or more of the operations may be omitted, and two or more of the operations may be performed in parallel or simultaneously without departing from the spirit and scope of the example embodiments described herein. Referring to FIG. 8, the ADC circuit may convert an analog input signal into an original digital output signal, in operation 810. In operation 820, the ADC circuit may detect overflow of the original digital output signal due to the analog input signal being out of an input dynamic range of an ADC module and may determine a current state of the original digital output signal as a normal state or an error state. In operation 830, the ADC circuit may output a corrected digital output signal based on the original digital output signal, when the current state of the original digital output signal is the normal state. In operation 840, the ADC circuit may output the corrected digital output signal based on a replacement output signal for replacing the original digital output signal, when the current state of the original digital output signal is the error state.

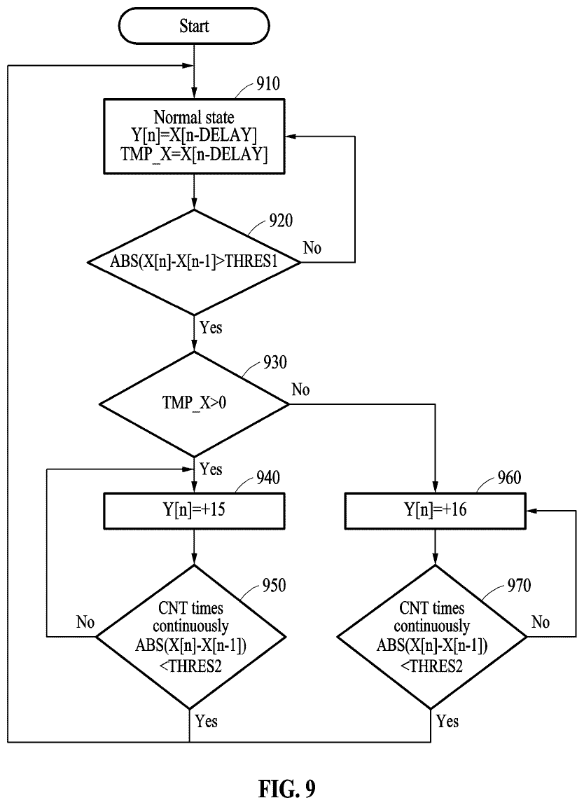

FIG. 9 illustrates an example of a process in which a corrected digital output signal is generated based on a current state of an original digital output signal. Operations 910 to 970 to be described hereinafter may be performed sequentially in the order and manner as shown and described below with reference to FIG. 9, but the order of one or more of the operations may be changed, one or more of the operations may be omitted, and two or more of the operations may be performed in parallel or simultaneously without departing from the spirit and scope of the example embodiments described herein. Referring to FIG. 9, in operation 910, a corrected digital output signal in a normal state may be output. The corrected digital output signal in a normal state may be expressed as Y [n]=X[n-DELAY]. Here, a temporary value may be determined. The temporary value may be expressed as TMP_X=X[n-DELAY].

In operation 920, it may be checked whether overflow has occurred. Whether overflow has occurred may be checked based on a condition such as ABS (X[n]−X[n−1])>THRES1. When overflow has occurred, a current state may change from the normal state to an error state. When overflow has not occurred, operation 910 may be performed again. When overflow has occurred, the current state may be determined as the error state. In operation 930, the temporary value may be compared to a reference value. FIG. 9 illustrates an example where the reference value is 0, but examples are not limited thereto.

When the temporary value is greater than the reference value, a corrected digital signal in the error state may be output based on a first sub-replacement value, in operation 940. The corrected digital signal may be expressed as Y [n]=A1 (TMP_X>REFR). FIG. 9 illustrates an example where A1=15 and REFR=0, but examples are not limited thereto. If the temporary value is less than the reference value, the corrected digital signal in the error state may be output based on a second sub-replacement value, in operation 960. The corrected digital signal may be expressed as Y [n]=A2 (TMP_X<REFR). FIG. 9 illustrates an example where A2=−16 and REFR=0, but examples are not limited thereto.

In operations 950 and 970, it may be checked whether overflow does not occur continuously. Whether overflow does not occur continuously may be checked based on a condition such as ABS (X[n]−X[n−1])<THRES2 occurring CNT times continuously. When overflow does not occur continuously, the current state may convert from the error state to the normal state.

FIG. 10 illustrates an example of a configuration of an electronic device using an ADC circuit. Referring to FIG. 10, an electronic device 1000 may include signal measuring instruments 1010, at least one processor 1020 (e.g., one or more processors), and at least one memory 1030 (e.g., one or more memories). Although not shown in FIG. 10, the electronic device 1000 may further include other elements such as a storage device, an input device, an output device, and a network device.

The signal measuring instruments 1010 may determine digital output signals corresponding to analog input signals measured from nerves. For example, the signal measuring instruments 1010 may include any one, any combination, or all of the components of FIGS. 1, 3A, 3B, and 5 discussed above. A signal measuring instrument of the signal measuring instruments 1010 may include an ADC module configured to convert an analog input signal of analog input signals into an original digital output signal, an error detection module configured to detect overflow of the original digital output signal due to the analog input signal being out of an input dynamic range of the ADC module and determine a current state of the original digital output signal as a normal state or an error state, and a correction module configured to output a digital output signal of digital output signals based on the original digital output signal, when the current state of the original digital output signal is the normal state, and output the digital output signal of the digital output signals based on a replacement output signal for replacing the original digital output signal, when the current state of a corrected digital output signal is the error state.

The at least one processor 1020 may determine biometric information of nerves based on the digital output signals. The biometric information may include a nerve signal, a nerve response, connectivity of nerves, connection strength of nerves, or a combination thereof. The at least one memory 1030 may include a non-transitory computer-readable storage medium storing instructions that, when executed by the at least one processor 1020, configure the at least one processor 1020 to perform any one, any combination, or all of the operations and/or methods disclosed herein with reference to FIGS. 1-9.

The ADC circuits, ADC blocks, error detection and correction blocks, filtering and decimation blocks, amplifying blocks, adjustment blocks, oscillator blocks, phase detection and quantization blocks, DAC blocks, error detection blocks, correction blocks, state machines, comparison and count blocks, delay selection blocks, output selection blocks, electronic devices, signal measuring instruments, processors, memories, ADC circuit 100, ADC block 110, error detection and correction block 120, filtering and decimation block 130, amplifying block 111, adjustment block 112, oscillator block 113, phase detection and quantization block 114, DAC block 115, error detection and correction block 300, error detection block 310, correction block 320, state machine 311, comparison and count block 312, delay selection block 322, comparison block 323, output selection block 324, ADC circuit 500, electronic device 1000, signal measuring instruments 1010, at least one processor 1020, and at least one memory 1030 described herein, including descriptions with respect to respect to FIGS. 1-10, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-10 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROM, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. An analog-to-digital converter (ADC) circuit comprising:
an ADC module configured to convert an analog input signal into an original digital output signal;
an error detection module configured to:
detect overflow of the original digital output signal due to the analog input signal being out of an input dynamic range of the ADC module; and
determine a current state of the original digital output signal as a normal state or an error state; and
a correction module configured to:
in response to the current state of the original digital output signal being the normal state, output a corrected digital output signal based on the original digital output signal; and
in response to the current state of the original digital output signal being the error state, output the corrected digital output signal based on a replacement output signal for replacing the original digital output signal.

2. The ADC circuit of claim 1, wherein the ADC module comprises:
a digital-to-analog converter (DAC) module configured to convert a previous original digital output signal into a previous analog output signal;
an adjustment module configured to adjust the analog input signal using the previous analog output signal;
an oscillator module configured to generate an oscillator signal controlled by an output signal of the adjustment module; and
a phase detection and quantization module configured to perform phase detection and quantization on the oscillator signal to generate the original digital output signal.

3. The ADC circuit of claim 1, wherein, for the detecting of the overflow, the error detection module is further configured to detect the overflow of the original digital output signal based on a difference between the original digital output signal and a previous original digital output signal.

4. The ADC circuit of claim 3, wherein, for the determining of the current state, the error detection module is further configured to, in response to the current state of the original digital output signal being the normal state and the difference between the original digital output signal and the previous original digital output signal exceeding a first threshold value, determine the current state of the original digital output signal as the error state.

5. The ADC circuit of claim 3, wherein, for the determining of the current state, the error detection module is further configured to, in response to the current state of the original digital output signal being the error state and the difference between the original digital output signal and the previous original digital output signal being less than a second threshold value, determine the current state of the original digital output signal as the normal state.

6. The ADC circuit of claim 5, wherein, for the determining of the current state, the error detection module is further configured to, in response to a state in which the difference between the original digital output signal and the previous original digital output signal is less than a second threshold value persisting for a threshold time, determine the current state of the original digital output signal as the normal state.

7. The ADC circuit of claim 1, wherein the correction module comprises:
a buffer module configured to store original digital values of the original digital output signal;
a delay selection module configured to select one of the original digital values as a temporary value from the buffer module based on a delay value that is set to correspond to a delay of the corrected digital output signal; and
an output selection module configured to select the temporary value or a replacement value as a digital value of the corrected digital output signal based on the current state of the original digital output signal.

8. The ADC circuit of claim 7, wherein the correction module further comprises a comparison module configured to compare the temporary value to a reference value.

9. The ADC circuit of claim 8, wherein
the replacement value comprises a first sub-replacement value and a second sub-replacement value, and
for the selecting of the temporary value or the replacement value, the output selection module is configured to, in response to the replacement value being selected as the digital value of the corrected digital output signal, select the first sub-replacement value or the second sub-replacement value as the digital value of the corrected digital output signal based on a comparison result between the temporary value and the reference value.

10. The ADC circuit of claim 7, wherein the replacement value is a boundary value of the original digital output signal or a temporary restoration value of a replacement waveform for temporarily restoring a waveform of the analog input signal that is out of the input dynamic range.

11. The ADC circuit of claim 10, further comprising a memory configured to store temporary restoration values of the replacement waveform including the temporary restoration value.

12. The ADC circuit of claim 1, further comprising:
a digital filter configured to perform digital filtering of the corrected digital output signal; and
a decimation filter configured to perform decimation on an output of the digital filter.

13. The ADC circuit of claim 1, wherein the ADC circuit is a delta sigma (DS) ADC.

14. The ADC circuit of claim 1, wherein the ADC circuit is a voltage-controlled oscillator (VCO)-based DS ADC.

15. An electronic device comprising:
the ADC circuit of claim 1; and
one or more processors configured to determine biometric information of one or more nerves based on the corrected digital output signal,
wherein the analog input signal is measured from the one or more nerves.

16. An electronic device comprising:
signal measuring instruments configured to determine digital output signals corresponding to analog input signals measured from nerves, the signal measuring instruments comprising an analog-to-digital converter (ADC) circuit comprising:
an analog-to-digital converter (ADC) module configured to convert an analog input signal of the analog input signals into an original digital output signal;
an error detection module configured to:
detect overflow of the original digital output signal due to the analog input signal being out of an input dynamic range of the ADC module; and
determine a current state of the original digital output signal as a normal state or an error state; and
a correction module configured to:
in response to the current state of the original digital output signal being the normal state, output a digital output signal of the digital output signals based on the original digital output signal; and
in response to the current state of the original digital output signal being the error state, output the digital output signal of the digital output signals based on a replacement output signal for replacing the original digital output signal; and
one or more processors configured to determine biometric information of the nerves based on the digital output signals including the output digital output signal.

17. The electronic device of claim 16, wherein the biometric information comprises any one or any combination of any two or more of a neural signal, a neural response, connectivity of nerves, and connection strength of nerves.

18. The electronic device of claim 16, wherein, for the detecting of the overflow, the error detection module is further configured to detect the overflow of the original digital output signal based on a difference between the original digital output signal and a previous original digital output signal.

19. The electronic device of claim 18, wherein, for the determining of the current state, the error detection module is further configured to, in response to the current state of the original digital output signal being the normal state and the difference between the original digital output signal and the previous original digital output signal exceeding a first threshold value, determine the current state of the original digital output signal as the error state.

20. A signal processing method comprising:
converting an analog input signal into an original digital output signal;
detecting overflow of the original digital output signal due to the analog input signal being out of an input dynamic range of an analog-to-digital converter (ADC) module and determining a current state of the original digital output signal as a normal state or an error state;
outputting a corrected digital output signal based on the original digital output signal, in response to the current state of the original digital output signal being the normal state; and
outputting the corrected digital output signal based on a replacement output signal for replacing the original digital output signal, in response to the current state of the original digital output signal being the error state.
